(19) United States
(12) Patent Application Publication
(10) Pub. No.: US 2024/0150622 A1
(43) Pub. Date: May 9, 2024

(54) ADHESIVE COMPOSITION AND FILM ADHESIVE, AND SEMICONDUCTOR PACKAGE USING FILM ADHESIVE AND PRODUCING METHOD THEREOF

(71) Applicant: FURUKAWA ELECTRIC CO., LTD., Tokyo (JP)

(72) Inventor: Minoru MORITA, Tokyo (JP)

(73) Assignee: FURUKAWA ELECTRIC CO., LTD., Tokyo (JP)

(21) Appl. No.: 18/543,182

(22) Filed: Dec. 18, 2023

Related U.S. Application Data
(63) Continuation of application No. PCT/JP2022/020970, filed on May 20, 2022.

(30) Foreign Application Priority Data
Sep. 28, 2021 (JP) 2021-157430

(51) Int. Cl. C09J 7/35; C09J 7/10; H01L 21/683; H01L 21/78

(52) U.S. Cl. CPC C09J 7/35; C09J 7/10; H01L 21/6836; H01L 21/78; C09J 2203/326; C09J 2301/304; C09J 2463/00; C09J 2475/00

(57) ABSTRACT

An adhesive composition containing an epoxy resin (A), an epoxy resin curing agent (B), a polyurethane resin (C), and an inorganic filler (D), wherein the polyurethane resin (C) has a tan δ peak top temperature of 0° C. or higher in dynamic mechanical analysis, and the proportion of the polyurethane resin (C) based on the total content of the epoxy resin (A) and the polyurethane resin (C) is from 2 to 50 mass %.

### CROSS-REFERENCE TO RELATED APPLICATIONS

This application is a Continuation of PCT International Application No. PCT/JP2022/020970 filed on May 20, 2022, which claims priority under 35 U.S.C. § 119 (a) to Japanese Patent Application No. 2021-157430 filed in Japan on Sep. 28, 2021. Each of the above applications is hereby expressly incorporated by reference, in its entirety, into the present application.

### FIELD OF THE INVENTION

The present invention relates to an adhesive composition and a film adhesive, and a semiconductor package using the film adhesive and a producing method thereof.

### BACKGROUND OF THE INVENTION

Stacked MCPs (Multi Chip Package) in which semiconductor chips are multistacked have recently been widely spread. Such stacked MCPs are mounted on memory packages for mobile phones or portable audio devices. Further, along with multi-functionality of mobile phones and the like, high densification and high integration of the package have also been advanced. Along with such advance, multistacking of the semiconductor chips has been advanced.

Thermosetting film adhesives (die attach films, die bond films) have been used for bonding a circuit board and a semiconductor chip or bonding semiconductor chips in the production process of such a memory package. Along with multistacking of the chips, the die attach film has also become increasingly thinner. Also, as miniaturization in the wiring rule of the wafer has been advanced, heat is more likely to be generated on the surface of the semiconductor element. Therefore, in order to dissipate heat to the outside of the package, a thermally conductive filler is blended in the die attach film to realize high thermal conductivity.

The semiconductor chip surface typically has a passivation film made of a polyimide layer for protecting a circuit surface. When the semiconductor chips are multi-stacked, the semiconductor chip with a die attach film is mounted on the passivation film surface. Therefore, high adhesion of the die attach film to the polyimide film is important for reliability of the semiconductor package.

As a material of a thermosetting film adhesive intended for so-called die attach film applications, for example, a composition obtained by combining an epoxy resin, a curing agent made of an epoxy resin, a polymer compound, and an inorganic filler (inorganic filler) is known. As the polymer compound, it has been proposed to use a polyurethane resin or a phenoxy resin (e.g., Patent Literatures 1 and 2).

### Citation List

### Patent Literature

Patent Literature 1: WO 2012/160916

Patent Literature 2: WO 2021/033368

### SUMMARY OF INVENTION

### Technical Problem

Usually, when a film adhesive is used as a die attach film, a semiconductor wafer bonded to the film adhesive is diced with a dicing tape as a base, and then divided (into chips). Thereafter, the divided semiconductor chip with the film adhesive is picked up from the dicing tape by using a jig such as a needle or a slider from the lower portion of the dicing tape, and is thermocompression-bonded to the surface of the circuit board or the surface of the semiconductor element.

Since the surface of the circuit board and the surface of the semiconductor element are not necessarily in a smooth surface state, air may be entrapped in the interface between the film adhesive and the adherend during the above thermocompression bonding. The entrapped air (void) reduces the strength of adhesion after thermal curing. Therefore, in a reliability test of the semiconductor package, generation of voids causes detachment at the interface between the adhesive and the adherend.

In addition, a jig mark caused by, for instance, a needle or a slider in the pickup step may remain on the surface of the film adhesive. Such a jig mark also causes voids at the time of thermocompression bonding. The jig mark-derived voids tend to become more apparent as the film adhesive is thinned (for example, less than 20 μm).

The present invention addresses the problem of providing: a film adhesive in which a jig mark (needle mark) in a pickup step hardly remains on a surface of the film adhesive even when the film adhesive is formed into a thin film, formation of voids can be suppressed during mounting, and detachment between the adhesive and an adherend can be suppressed while maintaining sufficient adhesion strength even in a strict reliability test of a semiconductor package; and an adhesive composition suitable for producing this film adhesive. In addition, the present invention provides a semiconductor package using this film adhesive and a producing method thereof.

### Solution to Problem

As a result of intensive studies in view of the above problems, the present inventors have found that the above problems can be solved by forming a film adhesive containing, as a composition, an epoxy resin, an epoxy resin curing agent, a polyurethane resin, and an inorganic filler in combination while using a specific amount of the polyurethane resin having a specific glass transition temperature.

The present invention is based on the above findings, and after further investigation, has been completed.

The above problems of the present invention have been solved by the following means.

[1]

An adhesive composition, containing:
an epoxy resin (A),
an epoxy resin curing agent (B),
a polyurethane resin (C), and
an inorganic filler (D),
   wherein the polyurethane resin (C) has a tan δ peak top temperature of 0° C. or higher in dynamic mechanical analysis, and
   wherein a proportion of the polyurethane resin (C) based on a total content of the epoxy resin (A) and the polyurethane resin (C) is from 2 to 50 mass %.
   [2]

The adhesive composition described in [1], wherein when a pre-cured film adhesive formed using the adhesive composition is heated at a temperature elevation rate of 5° C./min from 25° C., a melt viscosity at 120° C. ranges from 100 to 10,000 Pa·s.

[3]

A film adhesive produced from the adhesive composition described in [1] or [2].

[4]

The film adhesive described in [3], which has a thickness of 1 to 20 μm.

[5]

A method of producing a semiconductor package, including:
a first step of providing an adhesive layer by thermocompression bonding the film adhesive described in [3] or [4] to a back surface of a semiconductor wafer in which at least one semiconductor circuit is formed on a surface, and providing a dicing film with the adhesive layer interposed between the back surface and the dicing film;
a second step of integrally dicing the semiconductor wafer and the adhesive layer to obtain a semiconductor chip with an adhesive layer, the semiconductor chip including the semiconductor chip and a piece of the film adhesive on the dicing film;
a third step of removing the dicing film from the semiconductor chip with an adhesive layer and thermocompression bonding the semiconductor chip with an adhesive layer and a circuit board via the adhesive layer; and
a fourth step of thermally curing the adhesive layer.
   [6]

A semiconductor package wherein a semiconductor chip and a circuit board, or semiconductor chips are bonded with a thermally curable component of the film adhesive described in [3] or [4].

In the present invention, the numerical ranges expressed with the term “to” refer to ranges including, as the lower limit and the upper limit, the numerical values before and after the term “to”.

### Advantageous Effects of Invention

In a film adhesive of the present invention, any jig mark in a pickup step hardly remains on a surface of the film adhesive even when the film adhesive is formed into a thin film, formation of voids can be suppressed during mounting, and detachment between the adhesive and an adherend can be suppressed while maintaining sufficient adhesion strength even in a strict reliability test of a semiconductor package.

The adhesive composition of the present invention is suitable for providing the film adhesive.

The semiconductor package of the present invention can maintain sufficient strength of adhesion between the semiconductor chip and the adherend even in a strict reliability test, and is excellent in reliability.

The method of producing a semiconductor package according to the present invention makes it possible to maintain sufficient strength of adhesion between the semiconductor chip and the adherend even in a strict reliability test, thereby capable of producing a highly reliable semiconductor package.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of a method of producing a semiconductor package of the present invention.

FIG. 3 is a schematic longitudinal cross-sectional view illustrating a preferred embodiment of a third step of a method of producing a semiconductor package of the present invention.

FIG. 4 is a schematic longitudinal cross-sectional view illustrating a preferred embodiment of a step of connecting a bonding wire of a method of producing a semiconductor package of the present invention.

FIG. 5 is a schematic longitudinal cross-sectional view illustrating an example of an embodiment of multistacking of a method of producing a semiconductor package of the present invention.

FIG. 6 is a schematic longitudinal cross-sectional view illustrating an example of an embodiment of another multistacking of a method of producing a semiconductor package of the present invention.

FIG. 7 is a schematic longitudinal cross-sectional view illustrating a preferred embodiment of a semiconductor package produced by a method of producing a semiconductor package of the present invention.

### DESCRIPTION OF EMBODIMENTS

### Adhesive Composition

The adhesive composition of the present invention is a composition suitable for forming a film adhesive of the present invention.

The adhesive composition of the present invention contains an epoxy resin (A), an epoxy resin curing agent (B), a polyurethane resin (C), and an inorganic filler (D). The polyurethane resin (C) has a tan δ peak top temperature (i.e., a glass transition temperature, Tg) of 0° C. or higher in dynamic mechanical analysis. The proportion of the polyurethane resin (C) based on the total content of the epoxy resin (A) and the polyurethane resin (C) is controlled to 2 to 50 mass %.

Hereinafter, each component contained in the adhesive composition will be described.

### <Epoxy Resin (A)>

The epoxy resin (A) is preferably a thermosetting resin having an epoxy group, and preferably has an epoxy equivalent of 500 g/eq or less. The epoxy resin (A) may be liquid, solid, or semi-solid. The liquid in the present invention means that the softening point is less than 25° C. The solid means that the softening point is 60° C. or more. The semi-solid means that the softening point is between the softening point of the liquid and the softening point of the solid (25° C. or more and less than 60° C.). As the epoxy resin (A) used in the present invention, the softening point is preferably 100° C. or less from the viewpoint of obtaining a film adhesive that can reach low melt viscosity in a preferable temperature range (for example, 60 to 120° C.). Incidentally, in the present invention, the softening point is a value measured by the softening point test (ring and ball) method (measurement condition: in accordance with JIS-K7234:1986).

In the epoxy resin (A) used in the present invention, the epoxy equivalent is preferably from 150 to 450 g/eq from the viewpoint of increasing the crosslinking density of a thermally cured product. Note that, in the present invention, the epoxy equivalent refers to the number of grams of a resin containing 1 gram equivalent of epoxy group (g/eq).

The weight average molecular weight of the epoxy resin (A) is usually preferably less than 10,000 and more preferably 5,000 or less. The lower limit is not particularly limited, but is practically 300 or more.

The weight average molecular weight is a value obtained by GPC (Gel Permeation Chromatography) analysis.

Examples of the skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among these skeletons, a triphenylmethane type, a bisphenol A type, a cresol novolac type, or an orthocresol novolac type is preferable from the viewpoint of being capable of obtaining a film adhesive having low resin crystallinity and good appearance.

The content of the epoxy resin (A) is preferably 3 to 70 parts by mass, preferably 10 to 60 parts by mass, and more preferably 15 to 50 parts by mass as well as preferably 20 to 40 parts by mass, based on 100 parts by mass of the total content of components constituting the film adhesive (specifically, components other than a solvent, i.e., a solid content) in the adhesive composition of the present invention. By setting the content within the above preferable range, it is possible to enhance die attachment while suppressing the formation of any jig mark. In addition, the content may be set to the preferable upper limit or less. This can suppress generation of oligomer component, and the state of the film (e.g., film tack property) is unlikely to be changed in the case of a small change in temperature.

### <Epoxy Resin Curing Agent (B)>

As the epoxy resin curing agent (B), optional curing agents such as amines, acid anhydrides, and polyhydric phenols can be used. In the present invention, a latent curing agent is preferably used from the viewpoint of having a low melt viscosity, and being capable of providing a film adhesive that exhibits curability at a high temperature exceeding a certain temperature, has rapid curability, and further has high storage stability that enables long-term storage at room temperature.

Examples of the latent curing agent include a dicyandiamide compound, an imidazole compound, a curing catalyst composite-based polyhydric phenol compound, a hydrazide compound, a boron trifluoride-amine complex, an amine imide compound, a polyamine salt, a modified product thereof, or those of a microcapsule type. These may be used singly, or in combination of two or more types thereof. Use of an imidazole compound is more preferable from the viewpoint of providing even better latency (properties of excellent stability at room temperature and exhibiting curability by heating) and providing a more rapid curing rate.

The content of the epoxy resin curing agent (B) in the adhesive composition may be set, if appropriate, according to the type and reaction form of the curing agent. For example, the content can be 0.5 to 100 parts by mass, may be 1 to 80 parts by mass or 2 to 50 parts by mass, and is also preferably 4 to 20 parts by mass based on 100 parts by mass of the epoxy resin (A). In addition, when an imidazole compound may be used as the epoxy resin curing agent (B), the content of the imidazole compound is preferably from 0.5 to 10 parts by mass or preferably from 1 to 5 parts by mass based on 100 parts by mass of the epoxy resin (A). Setting the content of the epoxy resin curing agent (B) to the preferable lower limit or more can further reduce the curing time. On the other hand, setting the content to the preferable upper limit or less can suppress excessive remaining of the curing agent in the film adhesive. As a result, moisture absorption by the remaining curing agent can be suppressed, and thus the reliability of the semiconductor device can be improved.

### <Polyurethane Resin (C)>

The polyurethane resin (C) is a polymer having a urethane (carbamic acid ester) bond in the main chain. The polyurethane resin (C) has a constituent unit derived from a polyol and a constituent unit derived from a polyisocyanate, and may further have a constituent unit derived from a polycarboxylic acid. One kind of the polyurethane resin may be used singly, or two or more kinds thereof may be used in combination.

The polyurethane resin (C) has a tan δ peak top temperature (the same as a glass transition temperature, also called Tg) of 0° C. or higher in dynamic mechanical analysis. The Tg of the polyurethane resin (C) is preferably 2° C. or higher and more preferably 3° C. or higher. The Tg of the polyurethane resin (C) is usually 100° C. or lower, preferably 60° C. or lower, more preferably 50° C. or lower, and also preferably 45° C. or lower. When the Tg is within the above range, the polyurethane resin (C) is integrated with the epoxy resin and/or the inorganic filler at the time of formation of the film adhesive. As a result, the storage elastic modulus of the film adhesive is increased, for example. Also, jig marks after pickup are less likely to occur. This can achieve a characteristic that sufficiently passes a strict reliability test of the semiconductor package. Regarding the combination of the preferred upper limit and lower limit of the Tg of the polyurethane resin (C), the Tg is preferably from 0 to 100° C., more preferably from 2 to 60° C., still more preferably from 3 to 50° C., and still more preferably from 3 to 45° C.

The Tg is determined by the procedure described in Examples below. Specifically, a coating film is formed using a varnish obtained by dissolving a polyurethane resin in an organic solvent, and then dried to obtain a film made of the polyurethane resin. This film is measured by using a dynamic mechanical analyzer (trade name: Rheogel-E4000F, manufactured by UBM) under conditions: a measurement temperature range of 20 to 300° C., a temperature elevation rate of 5° C./min, and a frequency of 1 Hz. The obtained tan δ peak top temperature (temperature at which tan δ indicates maximum) is defined as a glass transition temperature Tg.

The polyurethane resin (C) itself has a storage elastic modulus at 25° C. of preferably 50 MPa or higher, more preferably 80 MPa or higher, and still more preferably 100 MPa or higher. The polyurethane resin (C) has a storage elastic modulus at 25° C. of usually 1000 MPa or less, more preferably 700 MPa, and preferably 650 MPa or less. The storage elastic modulus can be determined using a dynamic mechanical analyzer (Trade name: Rheogel-E4000F, manufactured by UBM Co., Ltd.). Specifically, a coating film is formed using a varnish obtained by dissolving a polyurethane resin in an organic solvent, and then dried to obtain a film made of the polyurethane resin. This film may be measured under the conditions: a measurement temperature range of 0 to 100° C., a temperature elevation rate of 5° C./min, and a frequency of 1 Hz, and the value of the storage elastic modulus at 25° C. can thus be determined. Regarding the combination of the preferred upper limit and lower limit of the storage elastic modulus at 25° C. of the polyurethane resin (C), the storage elastic modulus is preferably from 50 to 1000 MPa, more preferably from 80 to 700 MPa, and still more preferably from 100 to 650 MPa.

The weight average molecular weight of the polyurethane resin (C) is not particularly limited, and a polyurethane resin having a weight average molecular weight within a range of 5,000 to 500,000 is usually used.

The content of the polyurethane resin (C) is from 2 to 50 mass % as a proportion of the polyurethane resin (C) based on the total content of the epoxy resin (A) and the polyurethane resin (C), and is preferably from 4 to 40 mass %, more preferably from 6 to 35 mass %, still more preferably from 8 to 33 mass %, still more preferably from 10 to 30 mass %, still more preferably from 12 to 28 mass %, and still more preferably from 15 to 25 mass %.

The polyurethane resin (C) can be synthesized by an ordinarily method, and can also be obtained from the market. Examples of a commercially available product that can be applied as the polyurethane resin (C) include Dynaleo VA-9320M, Dynaleo VA-9310MF, or Dynaleo VA-9303MF (all manufactured by TOYOCHEM CO., LTD.).

### <Inorganic Filler (D)>

As the inorganic filler (D), an inorganic filler usually used in the adhesive composition can be used without particular limitation.

Examples of the inorganic filler (D) include each inorganic powder made of
ceramics, such as silica, clay, gypsum, calcium carbonate, barium sulfate, alumina (aluminum oxide), beryllium oxide, magnesium oxide, silicon carbide, silicon nitride, aluminum nitride, boron nitride;
metal or alloys, such as aluminum, copper, silver, gold, nickel, chromium, lead, tin, zinc, palladium, solder; and
carbons, such as carbon nanotube, or graphene.

The average particle diameter (d50) of the inorganic filler (D) is not particularly limited, but is preferably 0.01 to 6.0 μm, preferably 0.01 to 5.0 μm, more preferably 0.1 to 3.5 μm, and still more preferably 0.3 to 3.0 μm from the viewpoint of enhancing die attachment performance while suppressing the formation of any jig mark. The average particle diameter (d50) is a so-called median diameter, and refers to a particle diameter at which the cumulative volume is 50% when the particle size distribution is measured by the laser diffraction scattering method and the total volume of the particles is defined as 100% in the cumulative distribution.

The Mohs hardness of the inorganic filler is not particularly limited, and is preferably 2 or more and more preferably from 2 to 9 from the viewpoint of enhancing the die attach performance while suppressing the occurrence of any jig mark. The Mohs hardness can be measured with a Mohs hardness meter.

The inorganic filler (D) may contain a thermally conductive inorganic filler (inorganic filler having a thermal conductivity of 12 W/m·K or more) in an embodiment, or may contain a thermally non-conductive inorganic filler (inorganic filler having a thermal conductivity of less than 12 W/m·K) in an embodiment.

The inorganic filler (D) having thermal conductivity is a particle made of a thermally conductive material or a particle whose surface is coated with the thermally conductive material. The thermal conductivity of the thermally conductive material is preferably 12 W/m·K or more, and more preferably 30 W/m·K or more.

When the thermal conductivity of the thermally conductive material is the preferable lower limit or more, the amount of the inorganic filler (D) blended in order to obtain a desired thermal conductivity can be reduced. This suppresses increase in the melt viscosity of the die attach film and enables to further improve the filling property of the film into the unevenness of the substrate at the time of compression bonding to the substrate. As a result, generation of voids can be more reliably suppressed.

In the present invention, the thermal conductivity of the thermally conductive material means the thermal conductivity at 25° C., and the literature value for each material can be used. In a case where there is no description in the literatures, for example, the value measured in accordance with JIS R 1611:2010 can be used in the case of ceramics, or the value measured in accordance with JIS H 7801:2005 can be used in the case of metals in substitution for the literature value.

Examples of the inorganic filler (D) having thermal conductivity include thermally conductive ceramics, and preferred examples thereof include alumina particles (thermal conductivity: 36 W/m·K), aluminum nitride particles (thermal conductivity: 150 to 290 W/m·K), boron nitride particles (thermal conductivity: 60 W/m·K), zinc oxide particles (thermal conductivity: 54 W/m·K), silicon nitride particles (thermal conductivity: 27 W/m·K), silicon carbide particles (thermal conductivity: 200 W/m·K), and magnesium oxide particles (thermal conductivity: 59 W/m·K).

In particular, alumina particles having high thermal conductivity are preferable in terms of dispersibility and availability. Further, aluminum nitride particles and boron nitride particles are preferable from the viewpoint of having even higher thermal conductivity than that of alumina particles. In the present invention, alumina particles and aluminum nitride particles are preferable among these particles.

Additional examples include metal particles having higher thermal conductivity than ceramic, or particles surface-coated with metal. Preferred examples include polymer particles such as silicone resin particles or acrylic resin particles whose surfaces are coated with a single metal filler or metals such as silver (thermal conductivity: 429 W/m·K), nickel (thermal conductivity: 91 W/m·K), and/or gold (thermal conductivity: 329 W/m·K).

In the present invention, gold or silver particles are more preferable from the viewpoint of, in particular, high thermal conductivity and oxidation resistance deterioration.

The inorganic filler (D) may be subjected to surface treatment or surface modification. Examples of such surface treatment and surface modification include surface treatment and surface modification using a silane coupling agent, phosphoric acid or a phosphoric acid compound, and a surfactant. In addition to the items described in the present specification, for example, the descriptions of the silane coupling agent, the phosphoric acid or phosphoric acid compound, and the surfactant in the section of the thermally conductive filler in WO 2018/203527 or the section of the aluminum nitride filler in WO 2017/158994 can be applied.

A method of blending the inorganic filler (D) with resin components such as the epoxy resin (A), the epoxy resin curing agent (B), and the polyurethane resin (C) includes a method in which a powder inorganic filler and, if necessary, a silane coupling agent, phosphoric acid or a phosphoric acid compound, and a surfactant are directly blended (integral blending method), or a method in which a slurry inorganic filler obtained by dispersing an inorganic filler treated with a surface treatment agent such as a silane coupling agent, phosphoric acid or a phosphoric acid compound, and a surfactant in an organic solvent is blended.

A method of treating the inorganic filler (D) with a silane coupling agent is not particularly limited. Examples thereof include a wet method of mixing the inorganic filler (D) and a silane coupling agent in a solvent, a dry method of mixing the inorganic filler (D) and a silane coupling agent in a gas phase, and the above integral blending method.

In particular, the aluminum nitride particles contribute to high thermal conductivity, but tend to generate ammonium ions due to hydrolysis. It is therefore preferable that the aluminum nitride particles are used in combination with a phenol resin having a low moisture absorption rate and hydrolysis is suppressed by surface modification. As an aluminum nitride surface modification method, a method of providing a surface layer with an oxide layer of aluminum oxide to improve water proofness and then preforming surface treatment with phosphoric acid or a phosphoric acid compound to improve affinity with the resin is particularly preferable.

The silane coupling agent is a compound in which at least one hydrolyzable group such as an alkoxy group or an aryloxy group is bonded to a silicon atom. In addition to these groups, an alkyl group, an alkenyl group, or an aryl group may be bonded to the silicon atom. The alkyl group is preferably an alkyl group substituted with an amino group, an alkoxy group, an epoxy group, or a (meth)acryloyloxy group, and more preferably an alkyl group substituted with an amino group (preferably, a phenylamino group), an alkoxy group (preferably, a glycidyloxy group), or a (meth)acryloyloxy group.

Examples of the silane coupling agent include 2-(3,4-epoxycyclohexyl) ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, and 3-methacryloyloxypropyltriethoxysilane.

The silane coupling agent and the surfactant are contained in an amount of preferably 0.1 to 25.0 parts by mass, more preferably 0.1 to 10 parts by mass, and further preferably 0.1 to 2.0 parts by mass based on 100 parts by mass of the inorganic filler (D).

By adjusting the content of the silane coupling agent or the surfactant to the preferable range, it is possible to suppress peeling at the adhesion interface due to volatilization of an excessive silane coupling agent and surfactant during the heating process in semiconductor assembly (for example, a reflow process) while aggregation of the inorganic filler (D) is suppressed. As a result, generation of voids can be suppressed and die attachment performance can be improved.

Examples of the shape of the inorganic filler (D) include a flake shape, a needle shape, a filament shape, a spherical shape, or a scale shape. Preferred are spherical particles from the viewpoint of increased filling and fluidity.

In the adhesive composition of the present invention, the proportion of the inorganic filler (D) based on the total content of the epoxy resin (A), the epoxy resin curing agent (B), the polyurethane resin (C), and the inorganic filler (D) is preferably 5 to 70 vol %. When the content proportion of the inorganic filler (D) is equal to or more than the above lower limit, it is possible to improve the die attachment while suppressing the occurrence of jig marks when a film adhesive is formed. Further, a desired melt viscosity may be imparted. When the content is the above upper limit value or less, a desired melt viscosity can be imparted to the film adhesive, and generation of voids can be suppressed. In addition, the internal stress generated in the semiconductor package at the time of thermal change can be alleviated, and the adhesion strength can be improved in some cases.

The proportion of the inorganic filler (D) based on the total content of the epoxy resin (A), the epoxy resin curing agent (B), the polyurethane resin (C), and the inorganic filler (D) is preferably from 30 to 70 vol %, more preferably from 20 to 60 vol %, and further preferably from 20 to 50 vol %.

The content (vol %) of the inorganic filler (D) can be calculated from the contained mass and specific gravity of each of the epoxy resin (A), the epoxy resin curing agent (B), the polyurethane resin (C), and the inorganic filler (D).

### (Other Components)

The adhesive composition of the present invention may contain a polymer compound in addition to the epoxy resin (A), the epoxy resin curing agent (B), the polyurethane resin (C), and the inorganic filler (D) as long as the effects of the present invention are not impaired.

Examples of the polymer compound include natural rubber, butyl rubber, isoprene rubber, chloroprene rubber, silicone rubber, an ethylene-vinyl acetate copolymer, an ethylene-(meth)acrylic acid copolymer, an ethylene-(meth)acrylic acid ester copolymer, polybutadiene resin, polycarbonate resin, thermoplastic polyimide resin, polyamide resins such as 6-nylon and 6,6-nylon, (meth)acrylic resin, polyester resins such as polyethylene terephthalate and polybutylene terephthalate, polyamideimide resin, fluororesin, or phenoxy resin. These polymer compounds may be used singly, or in combination of two or more kinds thereof.

The adhesive composition of the present invention may further contain, for example, an organic solvent (e.g., methyl ethyl ketone), an ion trapping agent (ion capturing agent), a curing catalyst, a viscosity adjusting agent, an antioxidant, a flame retardant, and/or a coloring agent. The adhesive composition can contain, for example, other additives described in WO 2017/158994 A.

The proportion of the total content of the epoxy resin (A), the epoxy resin curing agent (B), the polyurethane resin (C), and the inorganic filler (D) in the adhesive composition of the present invention can be, for example, 60 mass % or more, preferably 70 mass % or more, further preferably 80 mass % or more, and may also be 90 mass % or more. Also, the proportion may be 100 mass %, and can be 95 mass % or less.

The adhesive composition of the present invention can be suitably used for obtaining the film adhesive of the present invention. However, the adhesive composition of the present invention is not limited to the film adhesive, and can also be suitably used for obtaining a liquid adhesive.

The adhesive composition of the present invention can be obtained by mixing the above components at a temperature at which the epoxy resin (A) is practically not cured. The order of mixing is not particularly limited. Resin components such as the epoxy resin (A) and the polyurethane resin (C) may be mixed together with a solvent, if necessary, and the inorganic filler (D) and the epoxy resin curing agent (B) may then be mixed. In this case, the mixing in the presence of the epoxy resin curing agent (B) may be performed at a temperature at which the epoxy resin (A) is practically not cured, and the mixing of the resin components in the absence of the epoxy resin curing agent (B) may be performed at a higher temperature.

From the viewpoint of suppressing thermal curing of the epoxy resin (A), the adhesive composition of the present invention is preferably stored under a temperature condition at 10° C. or lower before use (before being formed into a film adhesive).

### Film Adhesive

The film adhesive of the present invention is a film adhesive obtained from the adhesive composition of the present invention. Thus, the above-described epoxy resin (A), epoxy resin curing agent (B), polyurethane resin (C), and inorganic filler (D) are included. Meanwhile, the polyurethane resin (C) has a tan δ peak top temperature (glass transition temperature Tg), in dynamic mechanical analysis, of 0° C. or higher. The proportion of the polyurethane resin (C) based on the total content of the epoxy resin (A) and the polyurethane resin (C) is from 2 to 50 mass %.

When the film adhesive of the present invention is formed using the adhesive composition containing an organic solvent, the solvent is usually removed from the adhesive composition by drying. Thus, the content of the solvent in the film adhesive of the present invention is 1,000 ppm (ppm is on a mass basis) or less, and is usually 0.1 to 1,000 ppm.

Here, the “film” in the present invention means a thin film having a thickness of 200 μm or less. The shape, size, and the like of the film are not particularly limited, and can be appropriately adjusted according to a use form.

The film adhesive of the present invention can be suitably used as a die attach film in a semiconductor production process. In this case, the film adhesive of the present invention is less likely to have a jig mark in the pickup step, is excellent in die attachment performance, and also enables high reliability of the semiconductor package.

In the film adhesive of the present invention, when the film adhesive before curing is heated from 25° C. at a temperature elevation rate of 5° C./min, the melt viscosity at 120° C. is preferably in the range of 100 to 10,000 Pa·s, more preferably in the range of 200 to 10,000 Pa·s, more preferably in the range of 230 to 8,000 Pa·s, more preferably in the range of 300 to 6,000 Pa·s, more preferably in the range of 500 to 6,000 Pa·s, and further preferably in the range of 700 to 5,500 Pa·s from the viewpoint of enhancing the die attachment performance. In addition, the melt viscosity at 120° C. may be in the range of 700 to 3000 Pa·s, and is preferably in the range of 700 to 2500 Pa·s.

The melt viscosity can be determined by the method described in Examples described later.

The melt viscosity can be controlled, if appropriate, by the content of the inorganic filler (D) and the kind of the inorganic filler (D) as well as the kinds and contents of coexisting compounds or resins such as the epoxy resin (A), epoxy resin curing agent (B), and the polyurethane resin (C).

As used herein, the film adhesive before curing refers to one in which the epoxy resin (A) is in a state before thermal curing. The film adhesive before thermal curing specifically means a film adhesive which is not exposed to a temperature condition at 25° C. or higher after preparation of the film adhesive.

On the other hand, the film adhesive after curing refers to one in which the epoxy resin (A) is thermally cured. The above description is intended to clarify the characteristics of the adhesive composition of the present invention, and the film adhesive of the present invention is not limited to one that is not exposed to a temperature condition at 25° C. or higher.

The film adhesive of the present invention preferably has a thickness of 1 to 60 μm. The thickness is more preferably 3 to 30 μm, and particularly preferably 5 to 20 μm. The thickness of the film adhesive is preferably from 1 to 20 μm and more preferably from 5 to 15 μm from the viewpoint of further exerting the effect of the present invention, that is, exhibiting excellent die attachment performance while suppressing the occurrence of any jig mark and void during pickup even when the film adhesive is used as a thin film.

The thickness of the film adhesive can be measured by a contact type linear gauge method (desk-top contact type thickness measurement apparatus).

For example, the film adhesive of the present invention can be formed by preparing the adhesive composition (varnish) of the present invention, applying the composition onto a release-treated substrate film, and drying the composition as necessary. The adhesive composition usually contains an organic solvent.

As the release-treated substrate film, any release-treated substrate film that functions as a cover film of the obtained film adhesive may be used, and a common film can be employed, if appropriate. Examples thereof include release-treated polypropylene (PP), release-treated polyethylene (PE), and release-treated polyethylene terephthalate (PET).

A routine method can be adopted, if appropriate, as an application method, and examples thereof include methods using a roll knife coater, a gravure coater, a die coater, a reverse coater, and the like.

The drying may be performed by removing the organic solvent from the adhesive composition without curing the epoxy resin (A) to form a film adhesive, and can be performed, for example, by holding the composition at a temperature of 80 to 150° C. for 1 to 20 minutes.

The film adhesive of the present invention may be formed of the film adhesive of the present invention alone, or may have a form obtained by bonding a release-treated substrate film described above to at least one surface of the film adhesive. The film adhesive of the present invention may be a form obtained by cutting the film into an appropriate size, or a form obtained by winding the film into a roll form.

In the film adhesive of the present invention, the arithmetic average roughness Ra of at least one surface thereof (that is, at least one surface to be bonded to an adherend) is preferably 3.0 μm or less, and the arithmetic average roughness Ra of surfaces on both sides to be bonded to the adherend is more preferably 3.0 μm or less.

The arithmetic average roughness Ra is more preferably 2.0 μm or less, and further preferably 1.5 μm or less. The lower limit is not particularly limited, but is practically 0.1 μm or more.

From the viewpoint of suppressing curing of the epoxy resin (A), the film adhesive of the present invention is preferably stored under a temperature condition at 10° C. or lower before use (before curing).

### Semiconductor Package and Producing Method Thereof

Next, preferred embodiments of a semiconductor package and a method of producing the same according to the present invention will be described in detail with reference to the drawings. Note that in the descriptions and drawings below, the same reference numerals are given to the same or corresponding components, and overlapping descriptions will be omitted. FIGS. 1 to 7 are schematic longitudinal cross-sectional views each illustrating a preferred embodiment of each step of a method of producing a semiconductor package of the present invention.

In the method of producing a semiconductor package of the present invention, as a first step, as illustrated in FIG. 1, the film adhesive 2 (die attach film 2) of the present invention is first thermocompression bonded to the back surface of a semiconductor wafer 1 in which at least one semiconductor circuit is formed on a surface (that is, a surface of the semiconductor wafer 1 on which the semiconductor circuit is not formed), and a dicing film 3 (dicing tape 3) is then provided via this film adhesive 2. In FIG. 1, the film adhesive 2 is illustrated smaller than the dicing film 3, but the sizes (areas) of both films are set, if appropriate, according to the purpose. For the condition of thermocompression bonding, thermocompression bonding is performed at a temperature at which the epoxy resin (A) is not thermally cured actually. Examples include the condition at a temperature of about 70° C. and a pressure of about 0.3 MPa.

As the semiconductor wafer 1, a semiconductor wafer where at least one semiconductor circuit is formed on the surface can be appropriately used. Examples thereof include a silicon wafer, a SiC wafer, a GaAs wafer, and a GaN wafer. In order to provide a dicing die attach film of the present invention on the back surface of the semiconductor wafer 1, for example, a common apparatus such as a roll laminator or a manual laminator can be used, if appropriate.

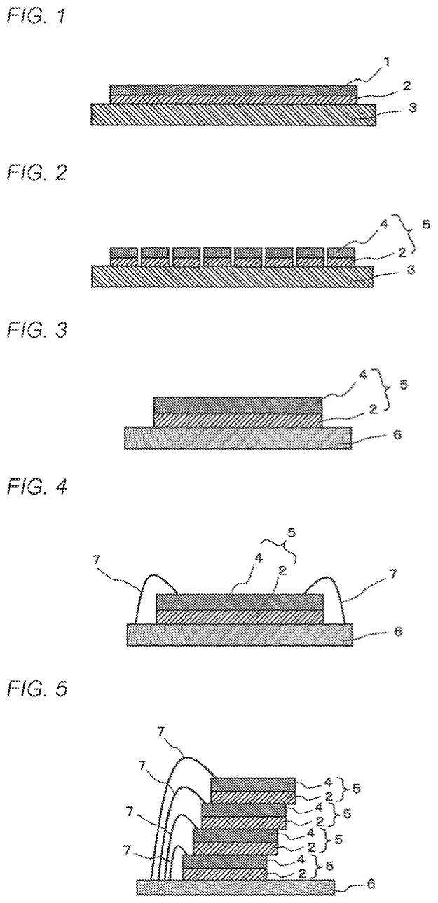

Next, as a second step, as illustrated in FIG. 2, the semiconductor wafer 1 and the die attach film 2 are integrally diced to give a semiconductor chip 5 with an adhesive layer on the dicing film 3, the semiconductor chip 5 including a semiconductor chip 4 obtained by dicing the semiconductor wafer and a piece of film adhesive 2 obtained by dicing the film adhesive 2. Further, an apparatus used for dicing is not particularly limited, and a common dicing apparatus can be used, if appropriate.

Next, as a third step, the dicing film is cured with energy rays as necessary to reduce the adhesive strength, and the film adhesive piece 2 is peeled off from the dicing film 3 by pickup. Then, as illustrated in FIG. 3, the semiconductor chip 5 with an adhesive layer and the circuit board 6 are thermocompression bonded via a piece of film adhesive 2 to mount the semiconductor chip 5 with an adhesive layer on the circuit board 6. As the circuit board 6, a substrate where a semiconductor circuit is formed on the surface can be used, if appropriate. Examples of such a substrate include a print circuit board (PCB), each lead frame, and a substrate where electronic components such as a resistive element and a capacitor are mounted on a surface of the substrate.

A method of mounting the semiconductor chip 5 with an adhesive layer on such a circuit board 6 is not particularly limited, and a common thermocompression bonding-mediated mounting method can be adopted, if appropriate.

Then, as a fourth step, the piece of film adhesive 2 is thermally cured. The temperature of the thermal curing is not particularly limited as long as the temperature is equal to or higher than a temperature at which thermal curing starts in the piece of film adhesive 2, and is adjusted, if appropriate, depending on the types of the epoxy resin (A), the polyurethane resin (C), and the epoxy curing agent (B) used. For example, the temperature is preferably from 100 to 180° C. and more preferably from 140 to 180° C. from the viewpoint of curing in a shorter time. If the temperature is too high, the components in the piece of film adhesive 2 tend to be volatilized during the curing process. This is likely to cause foaming. The duration of this thermal curing treatment may be set, if appropriate, according to the heating temperature, and can be, for example, from 10 to 120 minutes.

In the method of producing a semiconductor package of the present invention, it is preferable that the circuit board 6 and the semiconductor chip 5 with an adhesive layer are connected via a bonding wire 7 as illustrated in FIG. 4. Such a connection method is not particularly limited, and a common method, for example, a wire bonding method or a TAB (Tape Automated Bonding) method can be employed, if appropriate.

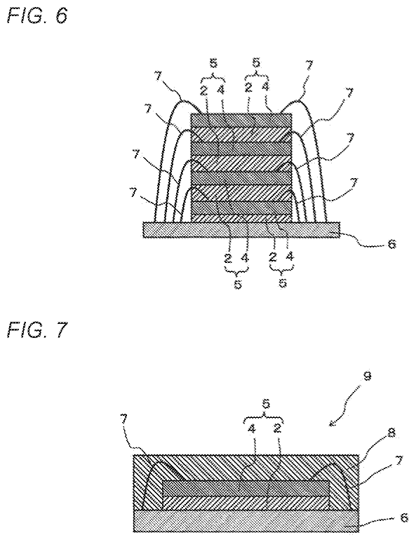

Further, a plurality of semiconductor chips 4 can be stacked by thermocompression bonding another semiconductor chip 4 to a surface of the mounted semiconductor chip 4, performing thermal curing, and then connecting the semiconductor chips 4 again to the circuit board 6 by wire bonding. Examples of the stacking method include a method of stacking the semiconductor chips in slightly different positions as illustrated in FIG. 5, or a method of stacking the semiconductor chips by increasing the thicknesses of the piece of film adhesive 2 of the second layer or later and thereby embedding the bonding wire 7 in each piece of film adhesive 2 as illustrated in FIG. 6.

In the method of producing a semiconductor package of the present invention, it is preferable to seal the circuit board 6 and the semiconductor chip 5 with an adhesive layer by using a sealing resin 8 as illustrated in FIG. 7. In this way, the semiconductor package 9 can be obtained. The sealing resin 8 is not particularly limited, and a common sealing resin that can be used for the production of the semiconductor package can be used, if appropriate. In addition, a sealing method using the sealing resin 8 is not particularly limited and a routinely conducted method can be employed.

### EXAMPLES

Hereinafter, the present invention will be described in more detail based on Examples and Comparative Examples. However, the present invention is not limited to the following Examples. Also, the room temperature means 25° C., MEK is methyl ethyl ketone, IPA is isopropyl alcohol, and PET is polyethylene terephthalate. “%” and “part” are on a mass basis unless otherwise specified.

### Example 1

In a 1,000-mL separable flask, 56 parts by mass of cresol novolac type epoxy resin (trade name: EOCN-104S; weight average molecular weight: 5,000; softening point: 92° C.; solid; epoxy equivalent amount: 218; manufactured by Nippon Kayaku Co., Ltd.), 49 parts by mass of bisphenol A type epoxy resin (trade name: YD-128; weight average molecular weight: 400; softening point: 25° C. or less; liquid; epoxy equivalent amount: 190; manufactured by NSCC Epoxy Manufacturing Co., Ltd.), and 120 parts by mass (30 parts by mass as a polyurethane resin) of polyurethane resin solution (trade name: Dynaleo VA-9320M; weight average molecular weight of polyurethane resin: 120,000; Tg: 39° C.; storage elastic modulus at 25° C.: 594 MPa; solvent: MEK/IPA mixed solvent; manufactured by TOYOCHEM CO., LTD.) were heated with stirring at 110° C. for 2 hours to prepare a resin varnish.

Subsequently, this resin varnish (225 parts by mass) was transferred to an 800-mL planetary mixer, and 196 parts by mass of alumina filler (trade name: AO-502; average particle diameter (d50): 0.6 μm; manufactured by Admatechs) was introduced to the mixer. Further, 2.0 parts by mass of imidazole type curing agent (trade name: 2PHZ-PW; manufactured by Shikoku Chemicals Corporation) and 3.0 parts by mass of silane coupling agent (trade name: S-510; manufactured by JNC Corporation) were introduced to the mixer, and the contents were then stirred for 1 hour at room temperature. Then, defoaming under vacuum was conducted, thus obtaining a mixed varnish (adhesive composition).

Thereafter, the resulting mixed varnish was applied onto a release-treated PET film (release film) having a thickness of 38 μm and then dried by heating at 130° C. for 10 minutes to produce a two-layer laminated film (release film-attached film adhesive) prepared by forming, on a release film, a film adhesive having a length of 300 mm, a width of 200 mm, and a thickness of 10 μm.

The epoxy resin is not cured after the drying, and the same applies to the following Examples and Comparative Examples.

### Example 2

An adhesive composition and a two-layer laminated film were obtained in the same manner as in Example 1 except that 120 parts by mass (30 parts by mass as a polyurethane resin) of polyurethane resin solution (trade name: Dynaleo VA-9310MF; weight average molecular weight: 110,000; Tg: 27° C.; storage elastic modulus at 25° C.: 289 MPa; solvent: MEK/IPA mixed solvent; manufactured by TOYOCHEM CO., LTD.) was used.

### Example 3

An adhesive composition and a two-layer laminated film were obtained in the same manner as in Example 1 except that 120 parts by mass (30 parts by mass as a polyurethane resin) of polyurethane resin solution (trade name: Dynaleo VA -9303MF; weight average molecular weight: 105,000; Tg: 4° C.; storage elastic modulus at 25° C.: 100 MPa; solvent: MEK/IPA mixed solvent; manufactured by TOYOCHEM CO., LTD.) was used.

### Example 4

An adhesive composition and a two-layer laminated film were obtained in the same manner as in Example 2 except that the amount of the polyurethane resin solution blended was 200 parts by mass (50 parts by mass as a polyurethane resin) and the amount of the alumina filler blended was 224 parts by mass.

### Example 5

An adhesive composition and a two-layer laminated film were obtained in the same manner as in Example 2 except that the amount of the polyurethane resin solution blended was 40 parts by mass (10 parts by mass as a polyurethane resin) and the amount of the alumina filler blended was 168 parts by mass.

### Example 6

An adhesive composition and a two-layer laminated film were obtained in the same manner as in Example 2 except that the amount of the alumina filler blended was 305 parts by mass.

### Comparative Example 1

An adhesive composition and a two-layer laminated film were obtained in the same manner as in Example 1 except that 30 parts by mass of polyurethane resin (trade name: T-8175N; weight average molecular weight: 80,000; Tg: −23° C.; storage elastic modulus at 25° C.: 3.4 MPa; manufactured by DIC Convestro Polymer Ltd.) was used as the polyurethane resin, and 90 parts by mass of cyclohexanone was further blended.

### Comparative Example 2

An adhesive composition and a two-layer laminated film were obtained in the same manner as in Example 1 except that 120 parts by mass (30 parts by mass as a polyurethane resin) of polyurethane resin solution (trade name: Dynaleo VA -9302MF; weight average molecular weight: 95,000; Tg: −5° C.; storage elastic modulus at 25° C.: 8.7 MPa; solvent: MEK/IPA mixed solvent; manufactured by TOYOCHEM CO., LTD.) was used.

### Comparative Example 3

An adhesive composition and a two-layer laminated film were obtained in the same manner as in Example 1 except that instead of the polyurethane resin, 30 parts by mass of acrylic resin (trade name: SG-280EK23; weight average molecular weight: 800,000; Tg: −29° C.; storage elastic modulus at 25° C.: 6.5 MPa; manufactured by Nagase ChemteX Corporation) was used, and 90 parts by mass of cyclohexanone was further blended.

### Comparative Example 4

An adhesive composition and a two-layer laminated film were obtained in the same manner as in Example 1 except that instead of the polyurethane resin, 30 parts by mass of bisphenol A type phenoxy resin (trade name: YP-50; weight average molecular weight: 70,000; Tg: 85° C.; storage elastic modulus at 25° C.: 1,700 MPa; manufactured by NIPPON STEEL Epoxy Manufacturing Co., Ltd.) was used, and 90 parts by mass of MEK was further blended.

### Comparative Example 5

An adhesive composition and a two-layer laminated film were obtained in the same manner as in Example 2 except that the amount of the polyurethane resin solution blended was 520 parts by mass (130 parts by mass as a polyurethane resin) and the amount of the alumina filler blended was 337 parts by mass.

### Comparative Example 6

An adhesive composition and a two-layer laminated film were obtained in the same manner as in Example 2 except that the amount of the polyurethane resin blended was 8 parts by mass (2 parts by mass as a polyurethane resin) and the amount of the alumina filler blended was 157 parts by mass.

### Test Example

### <To Determine tan δ Peak Top Temperature (Glass Transition Temperature (Tg)) in Dynamic Mechanical Analysis>

The solution of each polyurethane resin, acrylic resin, or phenoxy resin was applied onto a release-treated PET film (release film) having a thickness of 38 μm and dried by heating at 130° C. for 10 minutes, thereby producing a two-layer laminated film in which a resin film having a length of 300 mm, a width of 200 mm, and a thickness of 30 μm was formed on the release film. The resulting resin film was cut into a size of 5 mm×17 mm and the release film was then removed. The cut film was measured by using a dynamic mechanical analyzer (trade name: Rheogel-E4000F, manufactured by UBM) under the condition at a measurement temperature range of 20 to 300° C., a temperature elevation rate of 5° C./min, and a frequency of 1 Hz. The obtained tan δ peak top temperature (temperature at which tan δ indicates maximum) was defined as a glass transition temperature Tg.

### <Measurement of Melt Viscosity>

A square having a size of 5.0 cm×5.0 cm was cut out from the film adhesive with a release film as obtained in each Example or Comparative Example, and the film adhesive, which was cut out in a state where the release film was peeled, was laminated. This laminate was bonded using a hand roller on a stage at 70° C. to give a test piece with a thickness of about 1.0 mm. A change in viscosity resistance in a temperature range of 25 to 250° C. at a temperature elevation rate of 5° C./min was measured for this test piece by using a rheometer (RS6000, manufactured by Haake). The melt viscosities at 120° C. (Pa·s) of the film adhesive before curing were calculated from the obtained temperature-viscosity resistance curve.

### <To Evaluate Needle Marks>

The film adhesive with a release film as obtained in each Example or Comparative Example was first bonded to one surface of a dummy silicon wafer (size: 8 inch, thickness: 100 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator at room temperature and a pressure of 0.3 MPa. Then, dicing was performed from the dummy silicon wafer side to form squares each having a size of 5 mm×5 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a dummy chip with a film adhesive piece.

Next, the dummy chip with a film adhesive was picked up from the dicing tape with a die bonder (trade name: DB-800, manufactured by Hitachi High-Technologies Corporation) under the following conditions, and the state of needle marks on the film adhesive after pick-up was observed, and evaluation was performed according to the evaluation criteria below.

### (Pickup Conditions)

Four needles, needle R 150 (μm), needle pitch 3.5 mm, push-up speed 5 mm/sec, push-up height 200 μm, and pickup time 100 msec.

### (Evaluation Criteria)

AA: No needle mark was observed on the surface of the film adhesive in all of the 24 picked-up semiconductor chips.
A: Needle marks were observed on the surface of the film adhesive in 1 to 3 of the 24 picked-up semiconductor chips, and the number of needle marks on the surface of the film adhesive in which the needle marks were observed was 1 to 3.
B: Needle marks were observed on the surface of the film adhesive in 1 to 3 of the 24 picked-up semiconductor chips, and the number of needle marks on the surface of the film adhesive in which the needle marks were observed included 4.
C: Needle marks were observed on the surface of the film adhesive in 4 or more of the 24 picked-up semiconductor chips.

### <To Evaluate Die Attachment>

The film adhesive with a release film as obtained in each Example or Comparative Example was first bonded to one surface of a dummy silicon wafer (size: 8 inch, thickness: 100 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator at room temperature and a pressure of 0.3 MPa. Then, dicing was performed from the dummy silicon wafer side to form squares each having a size of 10 mm×10 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a dummy chip with a film adhesive.

Next, the dummy chip with a film adhesive was picked up from the dicing tape by using a die bonder (trade name: DB-800, manufactured by Hitachi High-Tech Corporation). Then, the film adhesive side of the dummy chip with a film adhesive piece was thermocompression bonded to the mounting surface side of a lead frame substrate (42Alloy-based, manufactured by Tappan Printing Co., Ltd.) under conditions at a temperature of 120° C. and a pressure of 0.1 MPa (load: 400 gf) for 1.0 seconds, Here, the mounting surface of the lead frame substrate is a metal surface having a slight surface roughness.

The presence or absence of voids at the interface between the film adhesive and the mounting surface of the lead frame substrate was observed for the dummy chip with a film adhesive which had been thermocompression bonded on the substrate, by using an ultrasonic testing apparatus (SAT) (FS300111, manufactured by Hitachi Power Solutions Co., Ltd.). Then, the die attachment was evaluated based on the following criteria.

### (Evaluation Criteria)

A: No void was observed in all the 24 dummy chips mounted.
B: Voids were observed in 1 or more and 3 or less of the 24 dummy chips mounted.
C: Voids were observed in 4 or more of the 24 dummy chips mounted.
   <Die Shear Strength after Moisture Absorption>

The film adhesive with a release film as obtained in each Example or Comparative Example was first bonded to one surface of a dummy silicon wafer (size: 8 inch, thickness: 400 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator at room temperature and a pressure of 0.3 MPa. Next, dicing was performed from the dummy silicon wafer side to form squares each having a size of 2 mm×2 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a dummy chip with a film adhesive.

Next, a dicing tape (trade name: K-8, manufactured by Furukawa Electric Co., Ltd.) and a dicing frame (trade name: DTF 2-8-1 H001, manufactured by DISCO Corporation) were bonded to the silicon wafer with a polyimide film (polyimide type; PIMEL, polyimide film manufactured by Asahi Kasei Electronics Ltd.; approx. 8 μm, silicon wafer of 700 μm thick, wafer size: 8 inches) on the surface on the silicon wafer side (the side opposite to the polyimide film) at room temperature and a pressure of 0.3 MPa by using a manual laminator. Next, dicing was performed from the dummy silicon wafer side to form squares each having a size of 12 mm>12 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation), thus obtaining a silicon chip with a polyimide film

Next, the dummy chip with a film adhesive piece was picked up from the dicing tape by using a die bonder (trade name: DB-800, manufactured by Hitachi High-Tech Corporation). Then, the film adhesive side of the dummy chip with a film adhesive piece was thermocompression bonded to the mounting surface side (polyimide film) of the polyimide film-attached silicon chip with a size of 12×12 mm under conditions at a temperature of 120° C. and a pressure of 0.5 MPa (load: 200 gf) for 1.0 seconds. This was placed in a dryer and heated at a temperature of 120° C. for 2 hours to thermally cure the film adhesive. Thereafter, by using a thermo-hygrostat (trade name: PR-1J, manufactured by ESPEC CORP.), the obtained sample was allowed to absorb moisture for 168 hours at the level of moisture sensitive level (MSL) Lv1 in a moisture absorption reflow test defined by the Semiconductor Technology Association JEDEC (temperature: 85° C., relative humidity: 85% RH, 168 hours). After that, the die shear strength (MPa) of the dummy chip with a film adhesive piece to the polyimide surface was measured using a bond tester (trade name: 4000 Universal Bond Tester, DAGE). Eight tests were averaged and calculated as the die shear strength after moisture absorption. In addition, the rate (100×after moisture absorption/before moisture absorption) of the die shear strength after moisture absorption to the die shear strength before moisture absorption (eight tests ware averaged) was defined as a die shear strength retention rate (%).

### <To Evaluate Reliability>

The film adhesive with a release film as obtained in each Example or Comparative Example was first bonded to the silicon wafer side of a silicon wafer with a polyimide film (polyimide type: PIMEL, a polyimide film manufactured by Asahi Kasei Electronics: approx. 8 μm, a silicon wafer thickness of 100 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing tape (trade name: K-13, manufactured by Furukawa Electric Co., Ltd.) and a dicing frame (trade name: DTF2-8-1H001, manufactured by DISCO Corporation) were bonded onto a surface of the film adhesive by using the same manual laminator at room temperature and a pressure of 0.3 MPa. Next, dicing was performed from the polyimide-attached silicon wafer side to form pieces each having a size of 8 mm×9 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a polyimide film-attached silicon chip with a film adhesive piece.

Then, the polyimide film-attached silicon chip with a film adhesive piece was picked up from the dicing tape by using a die bonder (trade name: DB-800, manufactured by Hitachi High-Tech Corporation). Then, the film adhesive side of the polyimide film-attached silicon chip with a film adhesive piece was thermocompression bonded to the mounting surface side of a lead frame substrate (42Alloy-based, manufactured by Tappan Printing Co., Ltd.) under conditions at a temperature of 120° C. and a pressure of 0.1 MPa (load: 720 gf) for 1.5 seconds. Further, under the same conditions, the film adhesive side of another polyimide film-attached silicon chip with a film adhesive piece was thermocompression bonded to the polyimide film surface of the polyimide film-attached silicon chip with a film adhesive piece as previously mounted. This was placed in a dryer and heated at a temperature of 120° C. for 2 hours to thermally cure the film adhesive, thereby producing a test piece.

Next, by using a molding apparatus (trade name: V1R, manufactured by TOWA), the test piece was sealed with a molding agent (KE-3000F5-2 manufactured by KYOCERA Corporation), and heated and thermally cured at a temperature of 180° C. for 5 hours to obtain a semiconductor package. By using a thermo-hygrostat (trade name: PR-1J, manufactured by ESPEC CORP.), the obtained semiconductor package was allowed to absorb moisture at the level of moisture sensitive level (MSL) Lv1 (temperature: 85° C., relative humidity: 85%, 168 hours) or the Lv2 level (temperature: 85° C., relative humidity: 60%, 168 hours) in a moisture absorption reflow test defined by the Semiconductor Technology Association JEDEC. Thereafter, heating treatment was performed at a temperature of 260° C. for 10 seconds in an IR reflow furnace. The heated semiconductor package was cut with a diamond cutter and observed under an optical microscope to inspect whether detachment occurred at the interface between the lead frame and the film adhesive piece and the interface between the polyimide film and the film adhesive piece. In this way, reliability was evaluated. Here, 24 semiconductor packages were assembled to evaluate reliability according to the following criteria.

### (Evaluation Criteria)

AA: After moisture was absorbed at a temperature of 85° C. and a relative humidity of 85% for 168 hours no detachment failure was observed in all 24 semiconductor packages.
A: The above AA was not applicable, but after moisture was absorbed at a temperature of 85° C. and a relative humidity of 60% for 168 hours, no detachment failure was observed in all 24 semiconductor packages.
B: After moisture was absorbed at a temperature of 85° C. and a relative humidity of 60% RH for 168 hours, a detachment failure occurred in one or more semiconductor packages, and all detachment sites occurred between the film adhesive and the lead frame.
C: After moisture was absorbed at a temperature of 85° C. and a relative humidity of 60% RH for 168 hours, a detachment failure occurred in one or more semiconductor packages, and at least one detachment failure occurred between the film adhesive and the polyimide film.

The above respective test results are shown in the following Tables.

TABLE 1

| | | | Example | | | | | |
|---|---|---|---|---|---|---|---|---|
| | | | 1 | 2 | 3 | 4 | 5 | 6 |
| Film | Epoxy | EOCN-104S (cresol novolac type epoxy resin) | 56 | 56 | 56 | 56 | 56 | 56 |
| adhesive | resin | YD-128 (liquid bisA-type epoxy resin) | 49 | 49 | 49 | 49 | 49 | 49 |
| composition | Polymer | VA-9320M (polyurethane resin. Tg 39° C. 594 MPa) | 30 | | | | | |
| (parts | | VA-9310MF (polyurethane resin, Tg 27° C., 289 MPa) | | 30 | | 50 | 10 | 30 |
| by mass) | | VA-9303MF (polyurethane resin, Tg 4° C., 100 MPa) | | | 30 | | | |
| | Inorganic | AO502 (average particle diameter: 0.5 μm; alumina filler) | 196 | 196 | 196 | 224 | 168 | 305 |
| | filler | AG-4-8F (average particle diameter: 2.0 μm; silver filler) | | | | | | |
| | | SO-25R (average particle diameter: 0.5 μm; silica filler) | | | | | | |

| | | | | | | |
|---|---|---|---|---|---|---|
| S-510 (epoxysilane type silane coupling agent) | 3 | 3 | 3 | 3 | 3 | 3 |
| 2PHZ-PW (imidazole-type curing agent) | 3 | 2 | 2 | 2 | 2 | 2 |
| Total solid content | 335 | 335 | 335 | 383 | 287 | 444 |
| Inorganic filler content (vol %) | 30.0% | 30.0% | 30.0% | 30.0% | 30.0% | 40.0% |
| Proportion of polyurethane resin based | 22.4% | 22.4% | 22.4% | 32.5% | 8.8% | 22.4% |
| on total of epoxy resin and polyurethane resin | | | | | | |

| | | | | | | |
|---|---|---|---|---|---|---|
| Melt viscosity before curing at 120° C. [Pa · s] | 1050 | 940 | 830 | 1900 | 230 | 1840 |
| Needle mark evaluation | AA | AA | AA | AA | A | A.A |
| Die attachment evaluation | A | A | A | A | A | A |
| Die shear strength (to polyimide surface; MPa) | 45 | 40 | 36 | 28 | 58 | 35 |
| Die shear strength after moisture absorption (to polyimide surface; MPa) | 40 | 35 | 30 | 23 | 50 | 30 |
| Die shear strength retention rate | 89% | 88% | 83% | 82% | 86% | 86% |
| Reliability evaluation | AA | AA | AA | AA | AA | AA |

TABLE 2

| | | | Comparative Example | | | | | |
|---|---|---|---|---|---|---|---|---|
| | | | 1 | 2 | 3 | 4 | 5 | 6 |
| Film | Epoxy | EOCN-104S (cresol novolac type epoxy resin) | 56 | 56 | 56 | 56 | 56 | 56 |
| adhesive | resin | YD-128 (liquid bisA-type epoxy resin) | 49 | 49 | 49 | 49 | 49 | 49 |
| composition | Polymer | T-8175N (polyurethane resin, Tg −23° C., 3.4 MPa) | 30 | | | | | |
| (parts | | VA-9302MF (polyurethane resin, Tg −5° C., 8.7 MPa) | | 30 | | | | |
| by mass) | | SG-280EK23 (acrylic resin, Tg −29° C., 6.5 MPa) | | | 30 | | | |
| | | YP-50 (bisA-type phenoxy resin, Tg 85° C., 1700 MPa) | | | | 30 | | |
| | | VA-9310MF (polyurethane resin, Tg 27° C., 289 MPa) | | | | | 130 | 2 |
| | Inorganic | AO502 | 196 | 196 | 196 | 196 | 337 | 157 |
| | filler | (average particle diameter: 0.5 μm; alumina filler) | | | | | | |

| | | | | | | |
|---|---|---|---|---|---|---|
| S-510 (epoxysilane type silane coupling agent) | 3 | 3 | 3 | 3 | 3 | 3 |
| 2PHZ-PW (imidazole-type curing agent) | 2 | 2 | 2 | 2 | 2 | 2 |
| Total solid content | 335 | 335 | 335 | 335 | 576 | 268 |
| Inorganic filler content (vol %) | 30.0% | 30.0% | 30.0% | 30.0% | 30.0% | 30.0% |
| Proportion of polymer resin based | 22.4% | 22.4% | 22.4% | 22.4% | 55.6% | 1.9% |
| on total of epoxy resin and polymer resin | | | | | | |

| | | | | | | |
|---|---|---|---|---|---|---|
| Melt viscosity before curing at 120° C. [Pa · s] | 750 | 840 | 2130 | 650 | 16500 | 430 |
| Needle mark evaluation | C | B | B | AA | AA | B |
| Die attachment evaluation | B | B | B | A | C | B |
| Die shear strength (to polyimide surface; MPa) | 30 | 35 | 28 | 38 | 12 | 18 |
| Die shear strength after moisture absorption (to polyimide surface; MPa) | 25 | 29 | 18 | 9 | 4 | 9 |
| Die shear strength retention rate | 83% | 83% | 64% | 24% | 24% | 33% |
| Reliability evaluation | A | A | A | B | C | B |

As shown in the above Tables 1 and 2, when the Tg of the polyurethane resin used in the film adhesive is lower than that specified in the present invention, needle marks are likely to remain after pick-up, and voids are likely to occur after die attachment. Also. Comparative Examples 1 and 2 exhibited favorable results in the reliability evaluation, but the results were clearly inferior to the case of using the polyurethane resin specified in the present invention.

In addition, when a resin other than the polyurethane resin was applied as a resin combined with the epoxy resin, the die shear strength retention rate was low, and the reliability was poor (Comparative Examples 3 and 4).

Even in the case of using the polyurethane resin specified in the present invention, when the content was larger than that specified in the present invention, voids were easily generated during mounting, and both the die shear strength and the retention rate thereof were low, resulting in poor reliability of the semiconductor package (Comparative Example 5). Conversely, when the content of the polyurethane resin was smaller than that specified in the present invention, needle marks were more likely to remain as compared with Comparative Example 5 (Comparative Example 6).

By contrast, any of the film adhesives having the component composition specified in the present invention hardly caused needle marks in the pick-up step, hardly caused voids during mounting, had sufficiently high die shear strength, could sufficiently retain the die shear strength even under high-temperature and high-humidity conditions, and had excellent reliability of the semiconductor package (Examples 1 to 6).

Having described our invention as related to the present embodiments, it is our intention that the present invention not be limited by any of the details of the description, unless otherwise specified, but rather be construed broadly within its spirit and scope as set out in the accompanying claims.

### DESCRIPTION OF SYMBOLS

1 Semiconductor wafer
2 Adhesive layer (film adhesive)
3 Dicing film (dicing tape)
4 Semiconductor chip
5 Semiconductor chip with film adhesive
6 Circuit board
7 Bonding wire
8 Sealing resin
9 Semiconductor package

1. An adhesive composition, comprising:
an epoxy resin (A),
an epoxy resin curing agent (B),
a polyurethane resin (C), and
an inorganic filler (D),
wherein the polyurethane resin (C) has a tan δ peak top temperature of 0° C. or higher in dynamic mechanical analysis, and
wherein a proportion of the polyurethane resin (C) based on a total content of the epoxy resin (A) and the polyurethane resin (C) is from 2 to 50 mass %.

2. The adhesive composition according to claim 1, wherein when a pre-cured film adhesive formed using the adhesive composition is heated at a temperature elevation rate of 5° C./min from 25° C., a melt viscosity at 120° C. ranges from 100 to 10,000 Pa·s.

3. A film adhesive obtained from the adhesive composition according to claim 1.

4. The film adhesive according to claim 3, which has a thickness of 1 to 20 μm.

5. A method of producing a semiconductor package, comprising:
a first step of providing an adhesive layer by thermocompression bonding the film adhesive according to claim 3 to a back surface of a semiconductor wafer in which at least one semiconductor circuit is formed on a surface, and providing a dicing film with the adhesive layer interposed between the back surface and the dicing film;
a second step of integrally dicing the semiconductor wafer and the adhesive layer to obtain a semiconductor chip with an adhesive layer, the semiconductor chip including the semiconductor chip and a piece of the film adhesive on the dicing film;
a third step of removing the dicing film from the semiconductor chip with an adhesive layer and thermocompression bonding the semiconductor chip with an adhesive layer and a circuit board via the adhesive layer; and
a fourth step of thermally curing the adhesive layer.

6. A semiconductor package wherein a semiconductor chip and a circuit board, or semiconductor chips are bonded with a thermally curable component of the film adhesive according to claim 3.
